(19) United States
(12) Patent Application Publication
(10) Pub. No.: US 2025/0072293 A1
(43) Pub. Date: Feb. 27, 2025

(54) DISPLAY MODULE

(71) Applicant: Wuhan China Star Optoelectronics Semiconductor Display Technology Co., Ltd., Wuhan (CN)

(72) Inventors: Ping HE, Wuhan (CN); Liang SUN, Wuhan (CN)

(21) Appl. No.: 18/522,322

(22) Filed: Nov. 29, 2023

(30) Foreign Application Priority Data
Aug. 23, 2023 (CN) 202311077516.1

(51) Int. Cl. H10N 39/00; H01L 25/16; H01L 33/64; H10N 30/00

(52) U.S. Cl. CPC H10N 39/00; H01L 25/167; H01L 33/645; H10N 30/704; H10N 30/88

(57) ABSTRACT

The present disclosure provides a display module, which includes a silicon-based micro light emitting diode display panel and a heat dissipation device. The heat dissipation device includes a heat dissipation cavity disposed on a back surface of the silicon-based micro light emitting diode display panel and an electro-deformation member disposed on a cavity bottom of the heat dissipation cavity. In case that the electro-deformation member is powered on, the electro-deformation member deforms to avoid a channel causing an external environment to be in communication with the heat dissipation cavity, so that external air enters the heat dissipation cavity. External air has a relatively low temperature and can carry away 10 heat of the silicon-based micro light emitting diode display panel, so as to reduce a temperature of the silicon-based micro light emitting diode display panel, and improve a heat dissipation capability of the display module.

### CROSS-REFERENCE TO RELATED APPLICATION

The present disclosure claims priority to and the benefit of Chinese Patent Application No. 202311077516.1, filed on Aug. 23, 2023, the disclosure of which is incorporated herein by reference in its entirety.

### FIELD OF INVENTION

The present disclosure relates to the field of display technologies, and in particular, to a display module.

### BACKGROUND OF INVENTION

Compared with conventional micro display technologies, a silicon-based micro light emitting diode (micro LED) display technology has advantages, such as excellent brightness, high luminous efficiency, low power consumption, a high response speed, high contrast, ultra-high resolution, and color saturation.

Currently, in a case that radiative recombination luminescence occurs inside a silicon-based micro LED chip, most of energy may be converted into heat energy, but an excessively high junction temperature of the chip may reduce luminous efficiency of an LED. In addition, a silicon-based micro LED display module is mainly used in a product with a high requirement on miniaturization, such as AR glasses, and therefore, how to improve a heat dissipation capacity of the silicon-based micro LED display module has become an important technical problem faced by the silicon-based micro LED display technology.

In view of this, it is necessary to provide a display module to alleviate such a shortcoming.

### SUMMARY OF INVENTION

Embodiments of the present disclosure provide a display module. Air movement inside the display module and temperature reduction of a silicon-based micro light emitting diode display panel may be accelerated, to improve a heat dissipation capability of the display module.

Embodiments of the present disclosure provide a display module, including:
a silicon-based micro light emitting diode display panel; and
a heat dissipation device, including:
   a heat dissipation cavity provided on a back surface of the silicon-based micro light emitting diode display panel; and
   an electro-deformation member disposed on a cavity bottom of the heat dissipation cavity,
wherein in a case that the electro-deformation member is powered on, the electro-deformation member deforms to avoid a channel through which an external environment is in communication with the heat dissipation cavity.

According to some embodiments of the present disclosure, the electro-deformation member includes a first electrode, a piezoelectric material layer, and a second electrode, and the piezoelectric material layer is disposed between the first electrode and the second electrode.

According to some embodiment of the present disclosure, the cavity bottom of the heat dissipation cavity is formed with an air inlet, and a cavity wall of the heat dissipation cavity is formed with an air outlet; and the electro-deformation member includes:
at least one deformation portion, wherein an orthographic projection of the deformation portion on the cavity bottom covers the air inlet; and
a fixed portion disposed on a periphery of the deformation portion and connected to the deformation portion, wherein an orthographic projection of the fixed portion on the cavity bottom does not overlap the air inlet;
wherein the fixed portion is fixedly connected to the cavity bottom, and the deformation portion is not connected to the cavity bottom; and in a case that the electro-deformation member is powered on, the deformation portion deforms toward the silicon-based micro light emitting diode display panel, there is a gap between the deformation portion and the cavity bottom, and the gap between the deformation portion and the cavity bottom causes the air inlet to be in communication with the inside of the heat dissipation cavity.

According to some embodiments of the present disclosure, the heat dissipation device further includes a baffle, the baffle is disposed between the electro-deformation member and the cavity bottom, and the baffle includes:
a non-movable portion fixedly connected to the cavity bottom, wherein an orthographic projection of the non-movable portion on the cavity bottom does not overlap the air inlet; and
a movable portion disposed on one side of the non-movable portion close to the air inlet, and connected to the non-movable portion, wherein the movable portion is not connected to the cavity bottom, and an orthographic projection of the movable portion on the cavity bottom covers the air inlet;
wherein in a case that the electro-deformation member deforms toward the silicon-based micro light emitting diode display panel, the movable portion warps toward the silicon-based micro light emitting diode display panel, there is a gap between the movable portion and the cavity bottom, and the gap between the movable portion and the cavity bottom causes the air inlet to be in communication with the inside of the heat dissipation cavity.

According to some embodiments of the present disclosure, in a case that the electro-deformation member is powered off or in a case that the electro-deformation member recovers to a state before deformation, the movable portion is attached to the cavity bottom and covers the air inlet to space the air inlet apart from the inside of the heat dissipation cavity.

According to some embodiments of the present disclosure, in a case that the electro-deformation member is powered off or when the electro-deformation member recovers to a state before deformation, the movable part is attached to the cavity bottom and covers the air inlet to space the air inlet apart from the inside of the heat dissipation cavity.

According to an embodiment of the present disclosure, the electro-deformation member includes:
a plurality of first deformation portions spaced apart from each other;
a plurality of second deformation portions, each of the plurality of second deformation portions is inserted between two adjacent ones of the plurality of first deformation portions or disposed on one side of one of the plurality of first deformation portions, wherein there is a gap between each of the plurality of first deformation portions and an adjacent one of the plurality of second deformation portions; and
a fixed portion disposed on a periphery of the plurality of first deformation portions and the plurality of second deformation portions and respectively connected to the plurality of first deformation portions and the plurality of second deformation portions;
wherein in a case that the electro-deformation member is powered on, an alternating current is applied to both the plurality of first deformation portions and the plurality of second deformation portions, a phase of the alternating current applied to the plurality of first deformation portions is different from a phase of the alternating current applied to the plurality of second deformation portions, both the plurality of first deformation portions and the plurality of second deformation portions vibrate, and the gap between each of the plurality of first deformation portions and the adjacent one of the plurality of second deformation portions causes the inside of the heat dissipation cavity to be in communication with the external environment.

According to some embodiments of the present disclosure, the phase of the alternating current applied to each of the plurality of first deformation portions is contrary to the phase of the alternating current applied to each of the plurality of second deformation portions,
wherein in a case that the electro-deformation member is powered on, in a case that each of the plurality of first deformation portions reaches a positive maximum amplitude, each of the plurality of second deformation portions reaches a negative maximum amplitude; and in a case that each of the plurality of first deformation portions reaches the negative maximum amplitude, each of the plurality of second deformation portions reaches the positive maximum amplitude.

According to some embodiments of the present disclosure, each of the plurality of first deformation portions and each of the plurality of second deformation portions are in a shape of a straight strip; or
each of the plurality of first deformation portions includes a plurality of first extension portions spaced apart from each other and extending toward each of the plurality of second deformation portions and a plurality of first depressed portions disposed between adjacent ones of the plurality of first extension portions, and each of the plurality of second deformation portions includes a plurality of second extension portions spaced apart from each other and extending toward each of the plurality of first deformation portions and a plurality of second depressed portions disposed between adjacent ones of the plurality of second extension portions; and in a case that the electro-deformation member is not powered on, the plurality of first extension portions are accommodated in the plurality of second depressed portions, and the plurality of second extension portions are accommodated in the plurality of first depressed portions.

According to some embodiments of the present disclosure, the cavity bottom of the heat dissipation cavity is of an open structure, a cavity wall of the heat dissipation cavity is of a closed structure, and the electro-deformation member covers the cavity bottom of the heat dissipation cavity.

According to some embodiments of the present disclosure, the display module further includes a heat dissipation support layer, and the heat dissipation support layer is disposed between the silicon-based micro light emitting diode display panel and the heat dissipation device;
wherein a cavity top of the heat dissipation cavity is of an open structure, and the heat dissipation support layer sealingly covers the cavity top of the heat dissipation cavity.

The embodiments of the present disclosure have the following beneficial effects: the embodiments of the present disclosure provide a display module. The display module includes a silicon-based micro light emitting diode display panel and a heat dissipation device. The heat dissipation device includes a heat dissipation cavity and an electro-deformation member. The heat dissipation cavity is disposed on a back surface of the silicon-based micro light emitting diode display panel, and the electro-deformation member is disposed on a cavity bottom of the heat dissipation cavity. In a case that the electro-deformation member is powered on, the electro-deformation member deforms to avoid a channel causing an external environment to be in communication with the heat dissipation cavity, so that external air enters the heat dissipation cavity. External air has a relatively low temperature and can carry away heat of the silicon-based micro light emitting diode display panel, so as to reduce a temperature of the silicon-based micro light emitting diode display panel, and improve a heat dissipation capability of the display module. In addition, the electro-deformation member has a relatively low requirement on a deformation space in a thickness direction, which can reduce a thickness of the heat dissipation device while enabling the heat dissipation device to have better heat dissipation performance, thereby considering both a requirement for a small volume of a silicon-based micro light emitting diode display panel and a requirement for high heat dissipation efficiency.

### BRIEF DESCRIPTION OF DRAWINGS

FIG. 1 is a schematic diagram of a structure of a display module according to some embodiments of the present disclosure.

FIG. 2 is a schematic diagram of deformation of an electro-deformation member in the display module shown in FIG. 1.

FIG. 3 is a schematic diagram of a structure of a baffle according to some embodiments of the present disclosure.

FIG. 4 is a schematic diagram of another structure of a display module according to some embodiments of the present disclosure.

FIG. 5 is a schematic diagram of still another structure of a display module according to some embodiments of the present disclosure.

FIG. 6 is a schematic diagram of a structure of a heat dissipation support layer according to some embodiments of the present disclosure.

FIG. 7 is a schematic diagram of a structure of another heat dissipation support layer according to some embodiments of the present disclosure.

FIG. 8 is a schematic diagram of further another structure of a display module according to some embodiments of the present disclosure.

FIG. 9 is a schematic planar diagram of a structure of an electro-deformation member in the display module shown in FIG. 8.

FIG. 10 is a schematic diagram of vibration of an electro-deformation member in the display module shown in FIG. 8.

FIG. 11 is a schematic planar diagram of a structure of another electro-deformation member in the display module shown in FIG. 8.

### DETAILED DESCRIPTION OF PREFERRED EMBODIMENTS

The following embodiments are described with reference to the accompanying drawings, and are used to exemplify particular embodiments that the present disclosure can be used to implement. The directional terms mentioned in the present disclosure, such as “above”, “below”, “front”, “back”, “left”, “right”, “inside ”, “outside”, and “side”, merely refer to the directions in the accompanying drawings. Therefore, the used direction terms are intended to describe and understand the present disclosure, but are not intended to limit the present disclosure. In the figures, structurally similar units are denoted by same reference numerals.

The present disclosure is further described below with reference to the accompanying drawings and specific embodiments.

The embodiments of the present disclosure provide a display module. Air movement inside the display module may be accelerated, cold air is sucked through an air inlet, the cold air is used to absorb heat of the silicon-based micro light emitting diode display panel and convert the heat into hot air, and the hot air is discharged through an air outlet. In this way, so that a temperature of the silicon-based micro light emitting diode display panel may be reduced, thereby improving a heat dissipation capability of the display module and light emitting efficiency of a light emitting device, and reduce power consumption of the silicon-based micro light emitting diode display panel.

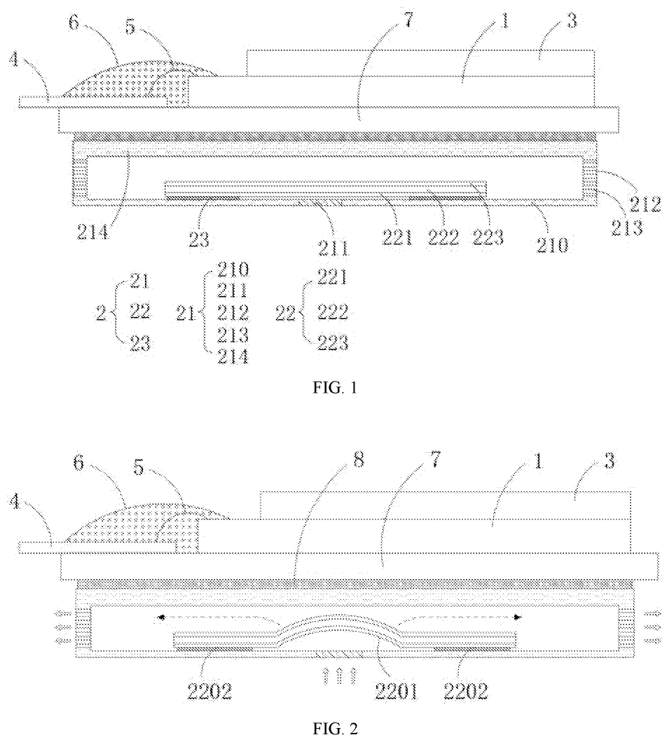

Referring to FIG. 1, which is a schematic diagram of a structure of a display module according to some embodiments of the present disclosure. The display module includes a silicon-based micro light emitting diode display panel 1 and a heat dissipation device 2. The heat dissipation device 2 is disposed on a back surface of the silicon-based micro light emitting diode display panel 1, and is configured to reduce a temperature of the silicon-based micro light emitting diode display panel 1.

In the embodiments of the present disclosure, the silicon-based micro light emitting diode display panel 1 includes a silicon-based back plate and a plurality of light emitting devices disposed on the silicon-based back plate. The light emitting device is a micro LED chip, and a size of the micro LED is less than 100 microns.

The display module further includes a cover plate 3, a flexible circuit board 4, a signal line 5, and a filling adhesive 6. The cover plate 3 is covered on a light emitting surface of the silicon-based micro light emitting diode display panel 1, the flexible circuit board 4 is electrically connected to the silicon-based micro light emitting diode display panel 1 through the signal line 5, and the filling adhesive 6 is disposed on the signal line 5 and is adhered to the flexible circuit board 4 and the silicon-based micro light emitting diode display panel 1, to fix the signal line 5 and the flexible circuit board 4.

Referring to FIG. 1, the heat dissipation device 2 includes a heat dissipation cavity 21 and an electro-deformation member 22. The heat dissipation cavity 21 is disposed on the back surface of the silicon-based micro light emitting diode display panel 1, the inside of the heat dissipation cavity 21 is of a hollow structure, and the electro-deformation member 22 is disposed on a cavity bottom of the heat dissipation cavity 21. In a case that the electro-deformation member 22 is powered on, the electro-deformation member 22 deforms to avoid a channel causing an external environment to be in communication with the inside of the heat dissipation cavity 21, to enable external air to enter the heat dissipation cavity 21. External air has a relatively low temperature and may carry away the heat of the silicon-based micro light emitting diode display panel 1, to accelerate reduction of the temperature of the silicon-based micro light emitting diode display panel 1, thereby improving the heat dissipation capability of the display module.

In some embodiments, a cavity bottom 210 of the heat dissipation cavity 21 is provided with an air inlet 211, a cavity wall 212 of the heat dissipation cavity 21 is provided with an air outlet 213, and both the air inlet 211 and the air outlet 213 are grid-shaped. In other words, the cavity bottom 210 has a bottom plate that seals a bottom of the heat dissipation cavity 21, and the air inlet 211 is provided on the bottom plate of the cavity bottom 210; and the cavity wall 212 has a side plate that seals a periphery of the heat dissipation cavity 21, and the air outlet is provided on the side surface of the cavity wall 212. In a case that neither the air inlet 211 nor the air outlet 213 is blocked, the inside of the heat dissipation cavity 21 may be in communication with the external environment through the air inlet 211 and the air outlet 213.

The electro-deformation member 22 is disposed on the bottom plate of the cavity bottom 210, and an orthographic projection of the electro-deformation member 22 on the cavity bottom 210 covers the air inlet 211. It is to be noted that, the cavity bottom 210 has an inner cavity bottom and an outer cavity bottom. The inner cavity bottom is a bottom of the hollow structure inside the heat dissipation cavity, and the outer cavity bottom is a bottom of an exposed portion of the heat dissipation cavity 21. That the electro-deformation member 22 is disposed on the cavity bottom 210 means that the electro-deformation member 22 is disposed on the inner cavity bottom of the heat dissipation cavity 21. The electro-deformation member 22 may deform under the action of an electric field, and after the electric field disappears, the electro-deformation member may recover to a state before deformation.

With reference to FIG. 1 and FIG. 2, FIG. 2 is a schematic diagram of deformation of an electro-deformation member in the display module shown in FIG. 1. In a case that the electro-deformation member 22 is powered off, the whole electro-deformation member 22 is attached to the cavity bottom 210, and the electro-deformation member 22 does not deform. In a case that the electro-deformation member 22 is powered on, the electro-deformation member 22 repeatedly deforms toward the silicon-based micro light emitting diode display panel 1.

In the embodiments of the present disclosure, the electro-deformation member 22 includes a first electrode 221, a piezoelectric material layer 223, and a second electrode 222. The piezoelectric material layer 223 is disposed between the first electrode 221 and the second electrode 222. Both the first electrode 221 and the second electrode 222 are made of metal such as copper or aluminum. Metal has good ductility, which can prevent the first electrode 221 and the second electrode 222 from breaking during deformation. A material of the piezoelectric material layer 223 is an organic piezoelectric material, and the organic piezoelectric material may be but is not limited to polyvinylidene difluoride (PVDF).

An alternating current is applied to the electro-deformation member 22, and an alternating electric field may be applied to the piezoelectric material layer 223 through the first electrode 221 and the second electrode 222, so that the piezoelectric material layer 223 may mechanically deform, and the whole electro-deformation member 22 mechanically deforms.

An action in which the electro-deformation member 22 repeatedly deforms toward the silicon-based micro light emitting diode display panel 1 and recovers to the state before deformation may be considered as vibration. A change frequency of the alternating current is adjusted, so that a vibration frequency of the electro-deformation member 22 in a vertical direction from a perspective shown in FIG. 2 may be adjusted. When a high-frequency alternating electric field reaches a frequency, the electro-deformation member may vibrate in an ultrasound-like frequency, an amplitude may range from several microns to tens of microns, and such vibration may generate strong negative pressure to drive air to flow.

In the embodiments of the present disclosure a frequency of the alternating current is 5 MHz. In some embodiments, the frequency of the alternating current is not limited to 5 MHz in the foregoing embodiment, which may also be 1 MHZ, 3 MHZ, 7 MHz, or 10 MHz, and only needs to be greater than or equal to 1 MHz and less than or equal to 10 MHz, so that it may be ensured that the electro-deformation member 22 generates vibration in the ultrasound-like frequency to meet a heat dissipation requirement of the display module.

In some embodiments, the frequency of the alternating current may increase as the temperature of the silicon-based micro light emitting diode display panel rises, and decrease as the temperature of the silicon-based micro light emitting diode display panel reduces. For example, the frequency of the alternating current is set to a plurality levels corresponding to different temperature ranges. The display module may further include a temperature sensor. The silicon-based micro light emitting diode display panel is cooled in a corresponding frequency of the alternating current according to a temperature of the silicon-based micro light emitting diode display panel detected by the temperature sensor.

Referring to FIG. 1 and FIG. 2, in a case that the electro-deformation member 22 deforms toward the silicon-based micro light emitting diode display panel, negative pressure may be generated above the air inlet 211, and the negative pressure may cause cold air in the external environment to enter the heat dissipation cavity 21 through the air inlet 211. When deforming toward the silicon-based micro light emitting diode display panel, the electro-deformation member 22 may extrude a space between the electro-deformation member 22 and a cavity top, so that hot air near the silicon-based micro light emitting diode display panel is discharged toward the cavity wall 212 of the heat dissipation cavity 21 and exhausted from the air outlet 213. After the hot air is discharged, the cold air flows to the cavity top, absorbs heat of the silicon-based micro light emitting diode display panel, and is converted into hot air, and the hot air is discharged through the air outlet 213 in the foregoing manner. These processes are repeated for a plurality times until the temperature of the silicon-based micro light emitting diode display panel reduces. The hot air finally discharged out of the heat dissipation cavity 21 may be discharged to external air through a heat dissipation channel of a whole machine equipped with the display module. In this way, a temperature reduction rate of the silicon-based micro light emitting diode display panel may be accelerated active heat dissipation of the electro-deformation member 22, to improve heat dissipation performance of the display module. In addition, the electro-deformation member 22 has a relatively low requirement on a deformation space in a thickness direction, which can reduce a thickness of the heat dissipation device while enabling the heat dissipation device to have better heat dissipation performance, thereby considering both a requirement for a small volume of a silicon-based micro light emitting diode display module and a requirement for high heat dissipation efficiency.

In the embodiments of the present disclosure, the heat dissipation device 2 has one electro-deformation member 22, and the cavity bottom 210 is provided with one air inlet 211. In some other embodiments, the cavity bottom 210 may also be provided with a plurality of air inlets 211 arranged at intervals. A quantity of electro-deformation members 22 may be the same as a quantity of air inlets 211, or may be less than a quantity of air inlets 211. For example, in a case that the heat dissipation device 2 has one electro-deformation member 22, one deformation member 22 may simultaneously cover a plurality of air inlets 211. In a case that the heat dissipation device 2 has a plurality of electro-deformation members 22, each deformation member 22 may cover one or more air inlets 211.

In the embodiments of the present disclosure, the heat dissipation cavity 21 is of a cubic structure, the heat dissipation cavity 21 has four cavity walls 212, and each cavity wall 212 may be provided with one or more air outlets 213. In some embodiments, an air outlet 213 may be provided only on any one of the cavity walls 212 or on two opposite cavity walls 212.

With reference to FIG. 1 and FIG. 2, the electro-deformation member 22 includes at least one deformation portion 2201 and a fixed portion 2202. The fixed portion 2202 is disposed on a periphery of the deformation portion 2201 and is connected to the deformation portion 2201. An orthographic projection of the deformation portion 2201 on the cavity bottom 210 covers the air inlet 211, and an orthographic projection of the fixed portion 2202 on the cavity bottom 210 does not overlap an air duct path of the air inlet 211.

In the embodiments of the present disclosure, the electro-deformation member 22 has one deformation portion 2201, the deformation portion 2201 and the fixed portion 2202 are of an integrated structure, the fixed portion 2202 is fixedly connected to the cavity bottom 210, and the deformation portion 2201 is not connected to the cavity bottom 210. In a case that the electro-deformation member 22 is powered on, since the fixed portion 2202 is fixed on the cavity bottom 210, the deformation portion 2201 is not connected to the cavity bottom 210, and the fixed portion 2202 does not deform. However, under the action of the electric field, the deformation portion 2201 may repeatedly deform and recover to a state before deformation. In a case that the electro-deformation member 22 is powered on, the deformation portion 2201 deforms toward the silicon-based micro light emitting diode display panel 1, and there is a gap between the deformation portion 2201 and the cavity bottom 210. The gap between the deformation portion 2201 and the cavity bottom 210 and the air inlet 211 form a channel causing the external environment to be in communication with the inside of the heat dissipation cavity 21. The gap between the deformation portion 2201 and the cavity bottom 210 causes the air inlet 211 to be in communication with the inside of the heat dissipation cavity 21.

During actual application, the electro-deformation member 22 may also have a plurality of deformation parts 2201. The plurality of deformation portions 2201 are disposed side by side and spaced apart from each other, and are connected to the fixed portion 2202.

An adhesive layer 23 is disposed between the fixed portion 2202 and the cavity bottom 210. The adhesive layer 23 is configured to adhere the fixed portion 2202 on the cavity bottom 210, and a material of the adhesive layer 23 is an insulation adhesive. The deformation portion 2201 is not connected to the cavity bottom 210 means that the adhesive layer or another structure configured to fix the deformation portion 2201 on the cavity bottom 210 is not disposed between the deformation portion 2201 and the cavity bottom 210.

In the embodiments of the present disclosure, a width of the deformation portion 2201 is greater than a width of the air inlet 211. With such a structure, the fixed portion 2202 is prevented from blocking the air inlet 211, and a case in which cold air cannot be sucked into the heat dissipation cavity 21 due to insufficient deformation of the deformation portion 2201.

In the embodiments of the present disclosure, a material of the heat dissipation cavity 21 is metal, which may specifically be, but is not limited to, aluminum alloy, stainless steel, titanium alloy, or the like, so that the heat dissipation cavity 21 has high strength and good heat dissipation performance. During actual application, the material of the heat dissipation cavity 21 is not limited to metal, and may also be another non-metallic material with high strength and good heat dissipation performance.

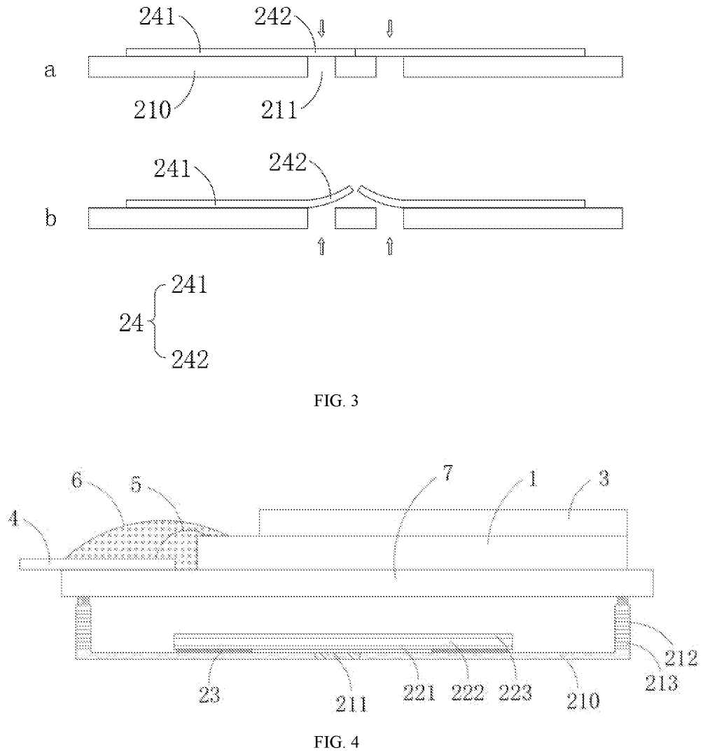

As shown in FIG. 3, which is a schematic diagram of a structure of a baffle according to some embodiments of the present disclosure. The heat dissipation device 2 further includes a baffle 24. The baffle 24 is disposed between the electro-deformation member 22 and the cavity bottom 210. The baffle 24 includes a non-movable portion 241 and a movable portion 242. The movable portion 242 is disposed on one side of the non-movable portion 241 close to the air inlet 211 and is connected to the non-movable portion 241. The non-movable portion 241 is fixedly connected to the cavity bottom 210, and the movable portion 242 is not connected to the cavity bottom 210. An orthographic projection of the non-movable portion 241 on the cavity bottom 210 does not overlap the air inlet 211, and an orthographic projection of the movable portion 242 on the cavity bottom 210 covers the air inlet 211. When negative pressure exists above the baffle 24, the baffle 24 warps toward the silicon-based micro light emitting diode display panel under the action of intensity of pressure, and forms a gap between the cavity bottom 210, so that the air inlet 211 is in communication with the inside of the heat dissipation cavity 21, and cold air in the external environment may enter the heat dissipation cavity through the air inlet 211 and the gap between the baffle 24 and the cavity bottom 210.

In the embodiments of the present disclosure, the non-movable portion 241 and the movable portion 242 are of an integrated structure. The baffle 24 is of a sheet structure, and the non-movable portion 241 and the movable portion 242 are different parts of the sheet structure. The non-movable portion 241 may be fixed on the cavity bottom 210 by using an adhesive.

In the embodiments of the present disclosure, the heat dissipation device 2 has two baffles 24, and the two baffles 24 are symmetrically disposed with respect to the air inlet 211 and covers the air inlet 211. During actual application, a quantity of baffles 24 is not limited to 2 in the foregoing embodiment, which may also be 1 or more than 2. This is not uniquely limited herein.

In the embodiments of the present disclosure, a material of the baffle 24 may be steel use stainless (SUS) or polyethylene glycol terephthalate (PET). In a case that the baffle 24 is made of PET, a thickness of the baffle may be 0.2 mm, 0.3 mm, 0.4 mm, 0.5 mm, or the like. In a case that the baffle 24 is made of SUS, the thickness of the baffle may be 0.03 mm, 0.05 mm, 0.07 mm, 0.1 mm, or the like, which can ensure stiffness of the baffle 24, and ensure that the baffle 24 may not deform when the electro-deformation member 22 recovers to an original state.

With reference to FIG. 3, part a in FIG. 3 shows a state of the baffle 24 in a case that the electro-deformation member is powered off or in a case that the electro-deformation member recovers to a state before deformation. In a case that the electro-deformation member is powered off, the deformation portion of the electro-deformation member does not deform, and the movable portion 242 of the baffle 24 is attached to the cavity bottom 210 and covers the air inlet 211, to space the air inlet 211 apart from the inside of the heat dissipation cavity 21. In a case that the electro-deformation member recovers to the state before deformation, an airflow moving downward may be formed above the baffle 24. Under the action of the airflow, the movable portion 242 is attached to the cavity bottom 210 and cannot deform downward, and covers the air inlet 211, so that the airflow inside the heat dissipation cavity 21 cannot be discharged through the air inlet 211.

Part b in FIG. 3 shows a state of the baffle 24 when the electro-deformation member deforms toward the silicon-based micro light emitting diode display panel 1. In a case that the electro-deformation member deforms toward the silicon-based micro light emitting diode display panel, and negative pressure exists above the movable portion 242, the movable portion 242 warps toward the silicon-based micro light emitting diode display panel under the action of intensity of pressure and forms a gap between the cavity bottom 210. The gap between the movable portion 242 and the cavity bottom 210 causes the air inlet 211 to be in communication with the heat dissipation cavity 21, so that cold air (as shown by an arrow in the figure) in the external environment may enter the heat dissipation cavity through the air inlet 211 and the gap between the movable portion 242 and the cavity bottom 210.

With reference to the foregoing embodiments, the baffle 24 is arranged above the air inlet 211, so that the air inlet 211 can only be conducted in one way, which allows cold air in the external environment to enter the heat dissipation cavity 21 and does not allow air in the heat dissipation cavity 21 to be discharged through the air inlet 211, thereby improving heat dissipation efficiency of the heat dissipation device.

In the embodiments of the present disclosure, the display module may further include a heat dissipation support layer 7. The heat dissipation support layer 7 is arranged between the silicon-based micro light emitting diode display panel 1 and the heat dissipation device 2. The heat dissipation support layer 7 is attached to the back surface of the silicon-based micro light emitting diode display panel 1. The flexible circuit board 4 and the silicon-based micro light emitting diode display panel 1 are fixedly mounted on a same side surface of the heat dissipation support layer 7. The heat dissipation device 2 is fixedly connected to the heat dissipation support layer 7.

In some embodiments, a material of the heat dissipation support layer 7 is metal, that is, the heat dissipation support layer 7 is a metal heat dissipation support plate. The heat dissipation support layer 7 is disposed on the back surface of the silicon-based micro light emitting diode display panel 1, so that stable support and protection may be provided for the silicon-based micro light emitting diode display panel 1 and the flexible circuit board 4, and by utilizing good thermal conductivity of metal, heat of the silicon-based micro light emitting diode display panel 1 may be dissipated through the heat dissipation support layer 7 or may be transferred to the heat dissipation device 2 through the heat dissipation support layer 7, and then is discharged by using the heat dissipation device 2, thereby improving the heat dissipation performance of the display module.

In some embodiments, the silicon-based micro light emitting diode display panel 1 may be directly mounted on the heat dissipation cavity 21 of the heat dissipation device 2, that is, the cavity top of the heat dissipation cavity 21 is directly attached to the back surface of the silicon-based micro light emitting diode display panel 1 through a thermally conductive adhesive layer. The flexible circuit board 4 is bound to a silicon-based back plate of the silicon-based micro light emitting diode display panel 1. With such a structure, the heat dissipation device 2 may also meet the heat dissipation requirement of the display module.

In some embodiments, as shown in FIG. 1, a cavity top 214 of the heat dissipation cavity 21 is of a closed structure, and a cavity structure enclosed by the cavity top 214 and the cavity wall 212 and the cavity bottom 210 may be in communication with the external environment through the air inlet 211 and the air outlet 213.

Both a surface of the heat dissipation support layer 7 close to the silicon-based micro light emitting diode display panel 1 and a surface close to the heat dissipation device 2 are flat surfaces. A thermally conductive adhesive layer 8 is arranged between the cavity top 214 and the heat dissipation support layer 7, and the thermally conductive adhesive layer 8 is respectively adhered to the surface of the heat dissipation support layer 7 close to the heat dissipation device 2 and a surface of the cavity top 214. A material of the thermally conductive adhesive layer 8 may be any one or a combination of thermally conductive silicone grease and thermally conductive silver paste. The thermally conductive adhesive layer 8 is used to adhere the heat dissipation device 2 and the heat dissipation support layer 7, which may reduce overall thermal resistance of the display module.

As shown in FIG. 4, which is a schematic diagram of a structure of a display module according to some embodiments of the present disclosure. It is to be noted that, the structure of the display module shown in FIG. 4 is substantially same as the structure of the display module shown in FIG. 1, and a difference is as follows: In the embodiment shown in FIG. 4, a cavity top of the heat dissipation cavity 21 is of an open structure, and the heat dissipation support layer 7 sealingly covers the cavity top of the heat dissipation cavity 21.

In some embodiments, a size of the open structure is less than a size of the cavity top, the open structure may be provided with a plurality of openings, and a portion of the cavity top that is not provided with an opening may be adhered to the heat dissipation support layer 7 through dispensing or by using a high-temperature tape. Cold air entering the heat dissipation cavity 21 through the air inlet 211 may be in direct contact with the heat dissipation support layer 7 through the openings of the open structure and carry away heat of the heat dissipation support layer 7, so that the overall thermal resistance of the display module may be reduced.

In some embodiments, as shown in FIG. 4, the size of the open structure is same as the size of the cavity top, that is, the whole cavity top of the heat dissipation cavity 21 is an opening, and an edge of the open structure may be adhered to the heat dissipation support layer 7 through dispensing or by using the high-temperature tape. With such a structure, a heat exchange area between cold air and the heat dissipation support layer 7 may be further increased, thereby further reducing the overall thermal resistance of the display module.

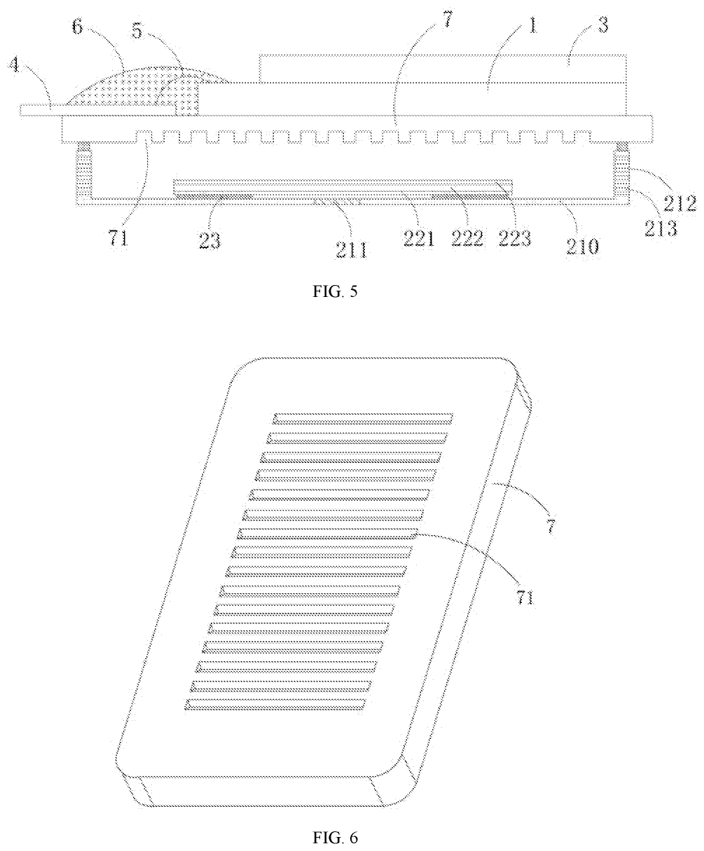

As shown in FIG. 5, which is a schematic diagram of a structure of a display module according to some embodiments of the present disclosure. It is to be noted that, the structure of the display module shown in FIG. 5 is substantially same as the structure of the display module shown in FIG. 4, and the difference lies in that: the surface of the heat dissipation support layer 7 close to the heat dissipation device 2 is provided with a plurality of strip-shaped grooves 71 disposed at intervals. A plurality of strip-shaped grooves 71 are formed on the surface of the heat dissipation support layer 7 close to the heat dissipation device 2, so that the heat exchange area between the heat dissipation support layer 7 and cold air may be increased, to improve heat dissipation efficiency of convection on the surface of the heat dissipation support layer 7 close to the heat dissipation device 2, thereby further improving the overall heat dissipation capability of the display module.

In the embodiments of the present disclosure, referring to FIG. 6, which is a schematic diagram of a structure of a heat dissipation support layer according to some embodiments of the present disclosure. The plurality of strip-shaped grooves 71 are disposed side by side and spaced apart from other on the surface of the heat dissipation support layer 7 close to the heat dissipation device 2. During actual application, the plurality of strip-shaped grooves 71 may also be staggered on the surface of the heat dissipation support layer 7 close to the heat dissipation device 2. This is not uniquely limited herein.

In the embodiments of the present disclosure, as shown in FIG. 5, a cross section of the strip-shaped groove 71 is rectangular. It is to be noted that, the cross section is a plane perpendicular to a length direction of the strip-shaped groove 71. During actual application, a shape of the cross section of the strip-shaped groove 71 is not limited to a rectangle, which may also be any one of a triangle, a trapezoid, and a semicircle, or a may be combination of at least two of a rectangle, a triangle, a trapezoid, and a semicircle.

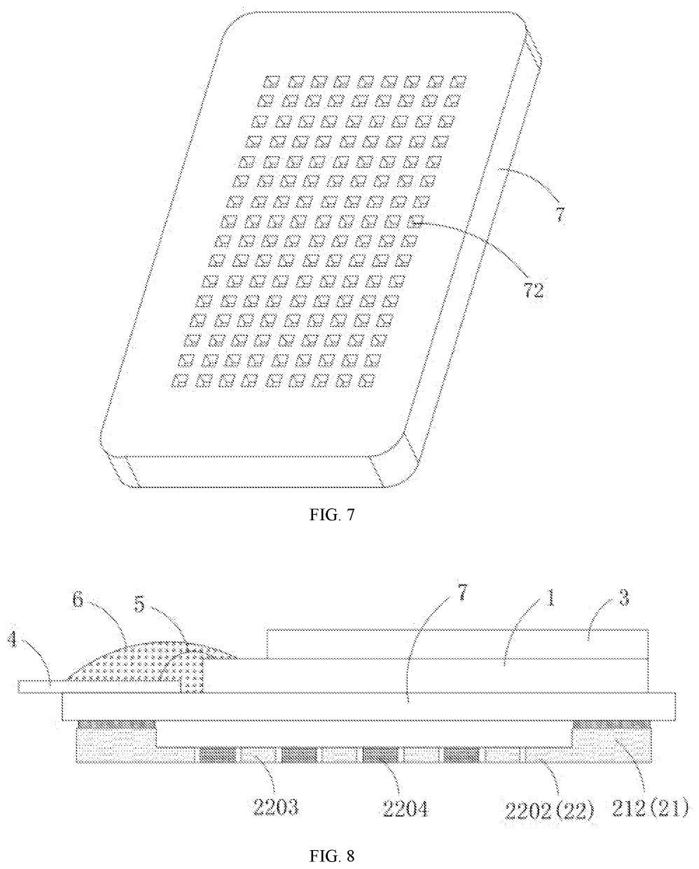

As shown in FIG. 7, which is a schematic diagram of a structure of another heat dissipation support layer according to some embodiments of the present disclosure. It is to be noted that, the structure of the heat dissipation support layer shown in FIG. 6 is substantially the same as the structure of the heat dissipation support layer shown in FIG. 6, and the difference lies in that: the surface of the heat dissipation support layer 7 close to the heat dissipation device 2 is provided with a plurality of openings 72 distributed in arrays, and the openings 72 are through holes or blind holes. A plurality of openings 72 are formed on the surface of the heat dissipation support layer 7 close to the heat dissipation device 2, so that the heat exchange area between the heat dissipation support layer 7 and cold air may be increased, to improve heat dissipation efficiency of convection on the surface of the heat dissipation support layer 7 close to the heat dissipation device 2, thereby further improving the overall heat dissipation capability of the display module.

In the embodiments of the present disclosure, a shape of the opening 72 is any one or a combination of at least two of a triangle, a rectangle, a trapezoid, and a circle.

With reference to FIG. 8, which is a schematic diagram of a structure of a display module according to some embodiments of the present disclosure. The structure is substantially the same as the structure of the display module shown in FIG. 4, and the difference lies in that:

The electro-deformation member 22 includes a plurality of first deformation portions 2203 and a plurality of second deformation parts 2204. The plurality of first deformation parts 2203 are spaced apart from each other, and the second deformation portion 2204 is inserted between adjacent first deformation portions 2203 or is disposed on one side of the first deformation portion 2203. There is a gap between the first deformation portion 2203 and the second deformation portion 2204. The fixed portion 2202 is disposed on a periphery of the first deformation portion 2203 and the second deformation portion 2204 is respectively connected to the first deformation portion 2203 and the second deformation portion 2204.

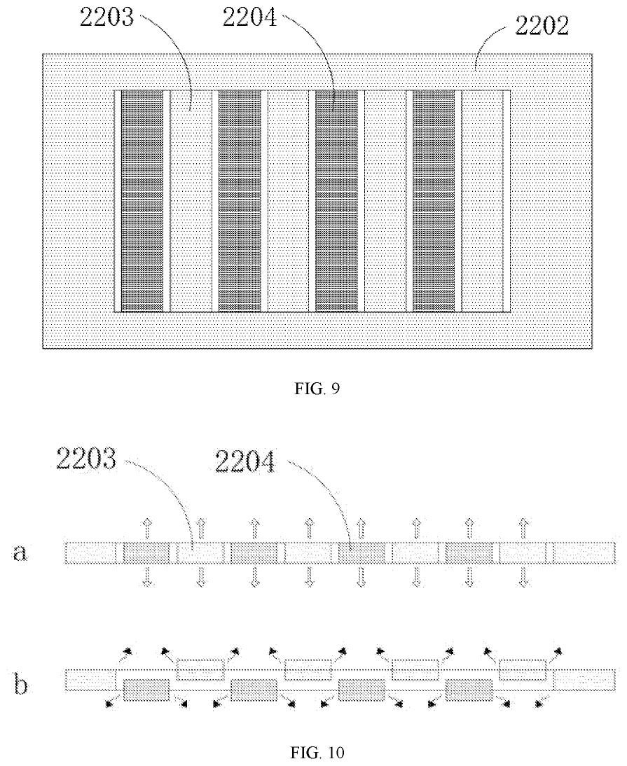

With reference to FIG. 8 and FIG. 9, FIG. 9 is a schematic planar diagram of a structure of an electro-deformation member in the display module shown in FIG. 8. One second deformation portion 2204 is inserted between every two first deformation parts 2203. It is to be noted that, FIG. 4 only illustrates a positional relationship and a structure of the first deformation portion 2203 and the second deformation portion 2204. A quantity of first deformation parts 2203 and second deformation parts 2204 shown in FIG. 4 does not indicate a quantity of first deformation parts 2203 and second deformation parts 2204 during actual application. The quantity of first deformation parts 2203 and second deformation parts 2204 may be set according to an actual requirement, for example, the quantity may be 2, 3, 4, or more. This is not limited herein.

In the embodiments of the present disclosure, in a case that the electro-deformation member 22 is powered on, an alternating current is applied to both the first deformation portion 2203 and the second deformation portion 2204, a phase of the alternating current applied to the first deformation portion 2203 is different from a phase of the alternating current applied to the second deformation portion 2204, both the first deformation portion 2203 and the second deformation portion 2204 vibrate, and the gap between the first deformation portion 2203 and the second deformation portion 2204 causes the inside of the heat dissipation cavity to be in communication with the external environment.

With reference to FIG. 10, which is a schematic diagram of vibration of an electro-deformation member in the display module shown in FIG. 8. Part a shows a state of the electro-deformation member 22 before energization. Before energization, the first deformation portion 2203, the second deformation portion 2204, and the fixed portion 2202 are on the same plane. In a case that an alternating current is applied, both the first deformation portion 2203 and the second deformation portion 2204 may vibrate in an arrow direction shown in the part a. Part b shows a state of the electro-deformation member after energization. Since the phase of the alternating current applied to the first deformation portion 2203 is different from the phase of the alternating current applied to the second deformation portion 2204, vibration of the first deformation portion 2203 and vibration of the second deformation portion 2204 are not synchronously performed. In this way, a relatively large gap is generated between the first deformation portion 2203 and the second deformation portion 2204, the gap between the first deformation portion 2203 and the second deformation portion 2204 forming a channel causing the external environment to be in communication with the inside of the heat dissipation cavity 21, external cold air may enter the heat dissipation cavity through the gap between the first deformation portion 2203 and the second deformation portion 2204 as shown by an arrow in the part b, and hot air in the heat dissipation cavity may also be discharged from the heat dissipation cavity through the gap between the first deformation portion 2203 and the second deformation portion 2204 as shown by the arrow in the part b, to accelerate a flow rate of air near the electro-deformation member 22, thereby quickly carrying away heat radiated from the silicon-based micro light emitting diode display panel.

In some embodiments, the phase of the alternating current applied to the first deformation portion 2203 is contrary to the phase of the alternating current applied to the second deformation portion 2204. With reference to the part b shown in FIG. 10, since the phase of the alternating current applied to the first deformation portion 2203 is contrary to the phase of the alternating current applied to the second deformation portion 2204, in a case that the electro-deformation member 22 is powered on, in a case that the first deformation portion 2203 reaches a positive maximum amplitude, the second deformation portion 2204 reaches a negative maximum amplitude. Similarly, in a case that the first deformation portion 2203 reaches the negative maximum amplitude, the second deformation portion 2204 reaches the positive maximum amplitude. With such a structure, two alternating electric fields with contrary phases are applied to each adjacent first deformation portion 2203 and second deformation portion 2204, so that the electro-deformation member 22 mechanically deforms. In a case that one deformation portion 2203 reaches the positive maximum amplitude, the adjacent second deformation portion 2204 just reaches the negative maximum amplitude, and the whole electro-deformation member 22 alternatively vibrates in this manner, so that the flow rate of air near the electro-deformation member 22 may be improved, thereby quickly carrying away heat radiated from the silicon-based micro light emitting diode display panel.

It is to be noted that, the positive maximum amplitude is a maximum amplitude of deformation that can be achieved by the first deformation portion 2203 or the second deformation portion 2204 toward a display panel, and the negative maximum amplitude is a maximum amplitude of deformation that can be achieved by the first deformation portion 2203 or the second deformation portion 2204 away from the display panel.

In some embodiments, as shown in FIG. 9, both the first deformation portion 2203 and the second deformation portion 2204 are in a shape of a straight strip, and the first deformation portion 2203 and the second deformation portion 2204 are arranged side by side and spaced apart from each other.

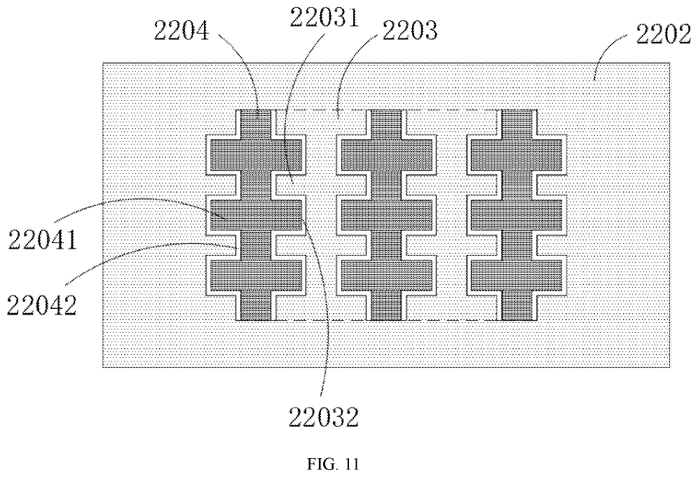

In some embodiments, as shown in FIG. 11, which is a schematic planar diagram of a structure of another electro-deformation member in the shown display module. The first deformation portion 2203 includes a plurality of first extension portions 22031 spaced apart from each other and extending toward the second deformation portion 2204 and a first depressed portion 22032 located between adjacent first extension portions 22031. The second deformation portion 2204 includes a plurality of second extension portions 22041 spaced apart from each other and extending toward the first deformation portion 2203 and a second depressed portion 22042 located between adjacent second extension portions 22041. Both the first deformation portion 2203 and the second deformation portion 2204 are of a serrated structure. In a case that the electro-deformation member 22 is not powered on, the first extension portion 22031 is accommodated in the second depressed portion 22042, and the second extension portion 22041 is accommodated in the first depressed portion 22032, to increase a length of a junction of the first deformation portion 2203 and the second deformation portion 2204, and further increase a heat exchange area between external cold air and the heat dissipation cavity, thereby further improving the heat dissipation performance of the display module.

During actual application, a shape of the first deformation portion 2203 and the second deformation portion 2204 is not limited to a straight strip or a serration in the foregoing embodiments, which may also be triangular, semicircular, trapezoidal, or S-shaped. This is not limited herein.

In the embodiments of the present disclosure, as shown in FIG. 8, the cavity bottom 210 of the heat dissipation cavity 21 is of an open structure, a cavity wall 212 of the heat dissipation cavity 21 is of a closed structure, and the electro-deformation member 22 covers the cavity bottom 210 of the heat dissipation cavity 21. The electro-deformation member 22 is used as a cavity bottom of the heat dissipation cavity 21. The electro-deformation member 22 and the cavity wall 212 of the heat dissipation cavity 21 enclose the heat dissipation cavity 21. The cavity wall 212 is adhered to a surface of the heat dissipation support layer 7 away from the silicon-based micro light emitting diode display panel by using a thermally conductive adhesive. The cavity wall 212 is not provided with an air outlet, external enters the heat dissipation cavity only through the gap between the first deformation portion 2203 and the second deformation portion 2204 of the electro-deformation member 22, and hot air in the heat dissipation cavity is also discharged only through the gap between the first deformation portion 2203 and the second deformation portion 2204 of the electro-deformation member 22. With such a structure, the electro-deformation member 22 may be used as a cavity bottom of the heat dissipation cavity, and structures such as an original cavity bottom and an air inlet provided on the original cavity bottom are omitted, so that complexity of the whole structure of the display module may be reduced, the heat dissipation device 2 may be directly attached to the silicon-based micro light emitting diode display panel, making it easier to conduct heat from the electro-deformation member 22 out of the whole machine of the display module.

The embodiments of the present disclosure have the following beneficial effects: The embodiments of the present disclosure provide a display module. The display module includes a silicon-based micro light emitting diode display panel and a heat dissipation device. The heat dissipation device includes a heat dissipation cavity and an electro-deformation member. The heat dissipation cavity is provided on a back surface of the silicon-based micro light emitting diode display panel, and the electro-deformation member is arranged on a cavity bottom of the heat dissipation cavity. In a case that the electro-deformation member is powered on, the electro-deformation member deforms toward the silicon-based micro light emitting diode display panel, so that external air enters the heat dissipation cavity. External air has a relatively low temperature and can carry away heat of the silicon-based micro light emitting diode display panel, so as to reduce a temperature of the silicon-based micro light emitting diode display panel, and improve a heat dissipation capability of the display module. In addition, the electro-deformation member has a relatively low requirement on a deformation space in a thickness direction, which can reduce a thickness of the heat dissipation device while enabling the heat dissipation device to have better heat dissipation performance, thereby considering both a requirement for a small volume of a silicon-based micro light emitting diode display module and a requirement for high heat dissipation efficiency.

In conclusion, although the present disclosure is disclosed above with reference to preferred embodiments, the foregoing preferred embodiments are not intended to limit the present disclosure. A person of ordinary skill in the art may make various modifications and embellishments without departing from the spirit and scope of the present disclosure. Therefore, the protection scope of the present disclosure falls within the scope defined by the claims.

What is claimed is:

1. A display module, comprising:
a silicon-based micro light emitting diode display panel; and
a heat dissipation device, comprising:
a heat dissipation cavity provided on a back surface of the silicon-based micro light emitting diode display panel; and
an electro-deformation member disposed on a cavity bottom of the heat dissipation cavity,
wherein in a case that the electro-deformation member is powered on, the electro-deformation member deforms to avoid a channel through which an external environment is in communication with the heat dissipation cavity.

2. The display module as claimed in claim 1, wherein the electro-deformation member comprises a first electrode, a piezoelectric material layer, and a second electrode, and the piezoelectric material layer is disposed between the first electrode and the second electrode.

3. The display module as claimed in claim 1, wherein the cavity bottom of the heat dissipation cavity is formed with an air inlet, and a cavity wall of the heat dissipation cavity is formed with an air outlet; and the electro-deformation member comprises:
at least one deformation portion, wherein an orthographic projection of the deformation portion on the cavity bottom covers the air inlet; and
a fixed portion disposed on a periphery of the deformation portion and connected to the deformation portion, wherein an orthographic projection of the fixed portion on the cavity bottom does not overlap the air inlet;
wherein the fixed portion is fixedly connected to the cavity bottom, and the deformation portion is not connected to the cavity bottom; and in a case that the electro-deformation member is powered on, the deformation portion deforms toward the silicon-based micro light emitting diode display panel, there is a gap between the deformation portion and the cavity bottom, and the gap between the deformation portion and the cavity bottom causes the air inlet to be in communication with the inside of the heat dissipation cavity.

4. The display module as claimed in claim 3, wherein the heat dissipation device further comprises a baffle, the baffle is disposed between the electro-deformation member and the cavity bottom, and the baffle comprises:
a non-movable portion fixedly connected to the cavity bottom, wherein an orthographic projection of the non-movable portion on the cavity bottom does not overlap the air inlet; and
a movable portion disposed on one side of the non-movable portion close to the air inlet, and connected to the non-movable portion, wherein the movable portion is not connected to the cavity bottom, and an orthographic projection of the movable portion on the cavity bottom covers the air inlet;
wherein in a case that the electro-deformation member deforms toward the silicon-based micro light emitting diode display panel, the movable portion warps toward the silicon-based micro light emitting diode display panel, there is a gap between the movable portion and the cavity bottom, and the gap between the movable portion and the cavity bottom causes the air inlet to be in communication with the inside of the heat dissipation cavity.

5. The display module as claimed in claim 4, wherein in a case that the electro-deformation member is powered off or in a case that the electro-deformation member recovers to a state before deformation, the movable portion is attached to the cavity bottom and covers the air inlet to space the air inlet apart from the inside of the heat dissipation cavity.

6. The display module as claimed in claim 2, wherein the electro-deformation member comprises:
a plurality of first deformation portions spaced apart from each other;
a plurality of second deformation portions, each of the plurality of second deformation portions is inserted between two adjacent ones of the plurality of first deformation portions or disposed on one side of one of the plurality of first deformation portions, wherein there is a gap between each of the plurality of first deformation portions and an adjacent one of the plurality of second deformation portions; and
a fixed portion disposed on a periphery of the plurality of first deformation portions and the plurality of second deformation portions and respectively connected to the plurality of first deformation portions and the plurality of second deformation portions;
wherein in a case that the electro-deformation member is powered on, an alternating current is applied to both the plurality of first deformation portions and the plurality of second deformation portions, a phase of the alternating current applied to the plurality of first deformation portions is different from a phase of the alternating current applied to the plurality of second deformation portions, both the plurality of first deformation portions and the plurality of second deformation portions vibrate, and the gap between each of the plurality of first deformation portions and the adjacent one of the plurality of second deformation portions causes the inside of the heat dissipation cavity to be in communication with the external environment.

7. The display module as claimed in claim 6, wherein the phase of the alternating current applied to each of the plurality of first deformation portions is contrary to the phase of the alternating current applied to each of the plurality of second deformation portions,
wherein in a case that the electro-deformation member is powered on, in a case that each of the plurality of first deformation portions reaches a positive maximum amplitude, each of the plurality of second deformation portions reaches a negative maximum amplitude; and in a case that each of the plurality of first deformation portions reaches the negative maximum amplitude, each of the plurality of second deformation portions reaches the positive maximum amplitude.

8. The display module as claimed in claim 6, wherein each of the plurality of first deformation portions and each of the plurality of second deformation portions are in a shape of a straight strip; or
each of the plurality of first deformation portions comprises a plurality of first extension portions spaced apart from each other and extending toward each of the plurality of second deformation portions and a plurality of first depressed portions disposed between adjacent ones of the plurality of first extension portions, and each of the plurality of second deformation portions comprises a plurality of second extension portions spaced apart from each other and extending toward each of the plurality of first deformation portions and a plurality of second depressed portions disposed between adjacent ones of the plurality of second extension portions; and in a case that the electro-deformation member is not powered on, the plurality of first extension portions are accommodated in the plurality of second depressed portions, and the plurality of second extension portions are accommodated in the plurality of first depressed portions.

9. The display module as claimed in claim 6, wherein the cavity bottom of the heat dissipation cavity is of an open structure, a cavity wall of the heat dissipation cavity is of a closed structure, and the electro-deformation member covers the cavity bottom of the heat dissipation cavity.

10. The display module as claimed in claim 1, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.

11. The display module as claimed in claim 2, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.

12. The display module as claimed in claim 3, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.

13. The display module as claimed in claim 4, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.

14. The display module as claimed in claim 5, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.

15. The display module as claimed in claim 6, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.

16. The display module as claimed in claim 7, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.

17. The display module as claimed in claim 8, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.

18. The display module as claimed in claim 9, wherein the display module further comprises a heat dissipation support layer, and the heat dissipation support layer is disposed between the silicon-based micro light emitting diode display panel and the heat dissipation device,
wherein a cavity top of the heat dissipation cavity is of an open structure, and the heat dissipation support layer sealingly covers the cavity top of the heat dissipation cavity.
